(19) United States
(12) Patent Application Publication
(10) Pub. No.: US 2014/0268611 A1
(43) Pub. Date: Sep. 18, 2014

(54) System For Applying Power Directly Into Power Connectors For Modular Systems

(71) Applicant: Emerson Network Power - Embedded Computing, Inc., Tempe, AZ (US)

(72) Inventors: Naufel C. NAUFEL, Tempe, AZ (US); Douglas L. SANDY, Chandler, AZ (US); Christopher M. MADSEN, Gilbert, AZ (US); James J. DORSEY, JR., Tempe, AZ (US)

(73) Assignee: Emerson Network Power - Embedded Computing, Inc., Tempe, AZ (US)

(21) Appl. No.: 13/799,484

(22) Filed: Mar. 13, 2013

(51) Int. Cl. H05K 5/00

(52) U.S. Cl. CPC H05K 5/0069
USPC 361/767; 361/760

(57) ABSTRACT

A system for providing electrical power connection across components mounted to a backplane of an electrical chassis includes a backplane having multiple apertures and front and rear faces. A daughter board faces the front face of the backplane. The daughter board has multiple traces with individual conductive pads. A power connector connected to the rear face of the backplane has multiple conductive members. Multiple fasteners each extend through both the daughter board and into the backplane to electrically couple each of the conductive pads of the daughter board to one of the conductive members of the power connector.

### FIELD

The present disclosure relates to modular electrical chassis having backplanes for power transfer to socket mounted component modules.

### BACKGROUND

This section provides background information related to the present disclosure which is not necessarily prior art.

Modular electrical systems commonly consist of a backplane having several slots or sockets wherein modules may be inserted. It is common to provide power to each slot through a connector mounted to the backplane. A centralized set of power connections on the backplane provides connection to an external power source. The backplane commonly provides conductive traces or planes which distribute the power from the external connection to each of the module slots. Due to resistive losses in the traces of the backplane, this configuration can become problematic when high slot power is required. The use of traces also significantly increases the cost and manufacturing complexity of the backplane designs.

### SUMMARY

This section provides a general summary of the disclosure, and is not a comprehensive disclosure of its full scope or all of its features.

According to several aspects, a system for providing electrical power connection across components mounted to a backplane of an electrical chassis includes at least one power terminal having a substantially planar first terminal body portion and a second terminal body portion. First and second posts integrally extend from the second terminal body portion. At least one aperture pair is created in a backplane having first and second conductive metal receiving tubes. The first and second posts individually extend into and frictionally engage one of the first or second receiving tubes. At least one wiring assembly has a terminal body connected to the first terminal body portion of the power terminal.

According to other aspects, a system for providing electrical power connection across components mounted to a backplane of an electrical chassis includes multiple power terminals each having a substantially planar first terminal body portion and a second terminal body portion. First and second posts integrally extend from the second terminal body portion of each of the power terminals. Multiple aperture pairs are created in a backplane, each pair having first and second conductive metal receiving tubes. The first and second posts of each of the power terminals individually extend into and frictionally engage one of the first or second receiving tubes of each of the aperture pairs. Multiple wiring assemblies each have a terminal body connected to the first terminal body portion of one of the power terminals.

According to further aspects, a system for providing electrical power connection across components mounted to a backplane of an electrical chassis includes a polymeric material connector body. Multiple power terminals each have a substantially planar first terminal body portion and a second terminal body portion. Each first terminal body portion is in contact with a first face of the connector body. First and second posts are integrally connected to the second terminal body portion of each of the power terminals and extend through the connector body. Multiple aperture pairs are created in a backplane, each pair having first and second conductive metal receiving tubes. The first and second posts of each of the power terminals individually freely extending from the connector body further extend into and frictionally engage one of the first or second receiving tubes of each of the aperture pairs. Multiple wiring assemblies each have a terminal body connected to the first terminal body portion of one of the power terminals.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a right front perspective view of a power distribution connector of the present disclosure;

FIG. 2 is a top right perspective view of a power terminal adapted for use with the power distribution connector of FIG. 1;

FIG. 3 is a left rear perspective view of the power distribution connector of FIG. 1;

FIG. 4 is a left front perspective assembly view of both an installed and a partially installed power distribution connector of FIG. 1;

FIG. 5 is a cross sectional side elevational view taken at section 5 of FIG. 4;

FIG. 6 is a front perspective view of a backplane assembly having multiple power distribution connectors of FIG. 1 installed thereon;

FIG. 7 is a cross sectional side elevational view similar to FIG. 4 of a further aspect of the present disclosure;

FIG. 8 is a front elevational view of a portion of the backplane of FIG. 6 showing connecting pads for installation of the power distribution connectors of FIG. 1;

FIG. 9 is an exploded front perspective view of the backplane assembly of FIG. 6;

FIG. 10 is an exploded front perspective view of a portion of the backplane assembly of FIG. 9;

FIG. 11 is a front elevational view of a portion of the backplane of FIG. 6;

FIG. 12 is an exploded rear perspective view of the backplane assembly of FIG. 6;

FIG. 13 is an exploded rear perspective view of another aspect of a backplane assembly similar to FIG. 6;

FIG. 14 is a partial exploded front perspective view of the backplane assembly of FIG. 13; and

FIG. 15 is a top perspective view of another aspect of a power terminal adapted for use with the power distribution connectors of the present disclosure.

Corresponding reference numerals indicate corresponding parts throughout the several views of the drawings.

### DETAILED DESCRIPTION

Example embodiments will now be described more fully with reference to the accompanying drawings.

Referring generally to FIGS. 1 and 2, according to several aspects a power distribution connection system 10 includes multiple connector assemblies 12 each having a molded, non-conductive and non-flammable polymeric material connector body 14 to which is attached multiple conductive metal power terminals 16. According to several aspects, each connector assembly 12 includes four (4) power terminals 16a, 16b, 16c, 16d. The power terminals 16 can be copper, or a material coated with a conductive metal such as copper. Each of the power terminals 16 includes a substantially planar first terminal body portion 18 which is cut or stamped for example from a metal strip. First terminal body portion 18 has a through aperture 20. A second terminal body portion 22 is bent or formed such that second terminal body portion 22 is oriented substantially normal to the first terminal body portion 18. First and second posts 24a, 24b which are substantially identical to each other are integrally connected to and extend co-planar with respect to second terminal body portion 22. Each of the first and second posts 24a, 24b are created using an “eye-of-the-needle” forming process such that each of the first and second posts 24a, 24b have curved or convex rounded edges 26a, 26b that oppose each other.

According to several aspects, the four power terminals 16a, 16b, 16c, 16d are arranged having the first terminal body portion 18 of each positioned in contact with a first or front face 28 of connector body 14 such that each through aperture 20 of the power terminal 16 is co-axially aligned with a corresponding one of four body apertures 30 created through connector body 14. The first and second posts 24a, 24b of each of the four power terminals 16a, 16b, 16c, 16d extend through and beyond connector body 14 as best seen in reference to FIG. 2. An integrally connected raised portion 32 of connector body 14 extends from front face 28, which is also made of the same polymeric material as connector body 14. Raised portion 32 acts to electrically insulate/isolate opposed ones of the power terminals 16a, 16d and 16b, 16c. According to further aspects, a second integrally connected raised portion 34 extending normal to raised portion 32 can also be provided between other pairs of power terminals, such as power terminals 16c, 16d. Raised portion 34 provides additional electrical isolation between these power terminals as well. A stepped or countersunk through aperture 36 is centrally positioned in raised portion 32, which receives a fastener (shown and described in reference to FIG. 3) to fasten connector body 14 to a backplane of an electrical component or cabinet.

Referring to FIG. 3 and again to FIGS. 1 and 2, a longitudinal slot 38 is created adjacent each of the body apertures 30 which extends through connector body 14. A width of each of the slots 38 is predetermined to frictionally receive and therefore frictionally retain the first and second posts 24a, 24b of one of the power terminals 16a, 16d and 16b, 16c. A portion of each of the first and second posts 24a, 24b extends through the connector body 14 and beyond a planar rear face 40 of connector body 14. According to several aspects, a thickness “A” of connector body 14 ranges between approximately 3.0 to 7.0 mm. According to additional aspects, each of the first and second posts 24a, 24b will extend beyond the rear face 40 by approximately 1.5 to 3.0 mm. These dimensions are exemplary, and are therefore not limiting to the disclosure/invention, and can vary depending on the parameters of the electrical component and/or cabinet design.

As further seen in FIG. 3, a threaded nut 42 can be positioned in coaxial alignment with each of the through apertures 20 and body apertures 30. Each of the nuts 42 is recessed into the connector body 14 in a correspondingly nut-shaped aperture 44 of the connector body 14 and can be substantially flush with the rear face 40. Each nut 42 will receive a threaded fastener which will be described in greater with respect to FIG. 4, which is installed from the front face 28 side of connector body 14.

Referring to FIG. 4 and again to FIGS. 1-3, a first connector assembly 12a is shown in an installed position connected to a backplane 46 such that its rear face 40 abuts a first planar face 48 of the backplane 46. A second connector assembly 12b is shown during an installation sequence which is accomplished as follows. The connector body 14 of second connector assembly 12b is aligned such that the first and second posts 24a, 24b of each of the power terminals 16a, 16b and 16c, 16d are aligned to be slidably and frictionally received in pre-formed aperture pairs 50, 52, 54, 56 created in backplane 46. For example, first and second posts 24a, 24b shown in FIG. 2 will be received in the first aperture pair 50 when rear face 40 abuts planar face 48 of backplane 46. After the second connector assembly 12b is thereby installed, a fastener 58 is inserted into through aperture 36 and fastened in an aperture 60 created in backplane 46 to engage connector body 14 of second connector assembly 12b to backplane 46 in an installed position.

With second connector assembly 12b in its installed position each of four substantially identical wiring assemblies 62, 64, 66, 68 are then connected to individual ones of the power terminals 16a, 16b and 16c, 16d. Each of the wiring assemblies 62, 64, 66, 68 includes an insulated wire 70 having a stripped wire lead 72 which is coupled such as by crimping to a terminal lead receiver 74 which is integrally connected to a connecting terminal 76. Each connecting terminal 76 has a connecting terminal aperture 78. A terminal fastener 80 is inserted through each of the connecting terminal aperture 78, the through aperture 20 of the terminal (such as terminal 16a), and the body aperture 30 of the connector body 14, and then threadably engaged with the nut 42 of the corresponding body aperture 30. This assembly positively engages the connecting terminal 76 with the power terminal 16. This installation process is repeated for each of the wiring assemblies 62, 64, 66, 68.

According to other aspects, the above installation steps can be modified such that the wiring assemblies 62, 64, 66, 68 are each connected to the connector body 14 before the connector body is connected to the backplane 46. This will leave only the single fastener connection of fastener 58 to be made to complete the installation of the connector assembly.

The connecting terminals 76 can have different services. For example, a connecting terminal 84 can be a power lead connected for example to a 48 VDC power source (not shown) and a connecting terminal 86 can be a ground lead. The power leads such as connecting terminal 84 are therefore separated by the raised portion 32 from the ground leads or connecting terminals 86. It is further noted that by rotating the connecting terminals of paired service leads by 180 degrees, such as connecting terminal 76 and connecting terminal 86, the terminal lead receiver 74 of each can be positioned such that the terminal lead receivers are oppositely directed with respect to the connecting terminals 76. For example, wiring assembly 62 can be positioned above or further away from the connector body 14 with respect to wiring assembly 64, thereby allowing a more compact “stacked” configuration of the wiring assemblies.

Referring to FIG. 5 and again to FIGS. 1-4, in an exemplary installation, first connector assembly 12a is installed with connector body 14 in direct contact with the first planar face 48 of backplane 46. During installation of first connector assembly 12a, the first and second posts 24a, 24b of each of the power terminals 16a, 16b and 16c, 16d are aligned to be slidably received in the pre-formed aperture pairs 50, 52, 54, 56 created in backplane 46. As shown, first and second posts 24a, 24b of power terminal 16d are received in preformed aperture pair 56. Preformed aperture pair 56 consists of a first metal receiving tube 88 which slidably and frictionally receives first post 24a and a second metal receiving tube 90 which slidably and frictionally receives second post 24b. The first and second receiving tubes 88, 90 can be entirely created from a conductive metal such as copper, or can be clad with a conductive metal. As the first and second posts 24a, 24b are received, the rounded edges 26a, 26b of each post deflect or compress toward each other to provide frictional engagement between opposed walls of the metal receiving tubes 88, 90. The other first and second posts 24a, 24b of the remaining power terminals 16a, 16b and 16c are aligned to be slidably received in pre-formed aperture pairs 50, 52, 54, for example as shown for first and second posts 24a, 24b of power terminal 16c which are received in aperture pair 54.

The first and second posts 24a, 24b occupy only a portion of the metal receiving tubes of the aperture pairs 50, 52, 54, 56. Another portion of each metal receiving tube of each aperture pair is occupied by a similar “eye-of-the-needle” post oppositely received through a second planar face 92 of backplane 46, which is oppositely facing with respect to first planar face 48. A zone 1 power connector 94 is attached to the second planar face 92 using its own posts such as third and fourth posts 96, 98, each slidably and frictionally received in one of the metal receiving tubes 88 or 90 respectively. The first and second posts 24a, 24b can directly contact the corresponding third or fourth posts 96, 98, however the disclosure is not limited to direct contact. The frictional contact of the posts with the walls of the respective metal receiving tube 88, 90 provides sufficient electrical contact for power transfer from the posts of the connector assemblies 12a, 12b to the zone 1 power connectors 94. According to further aspects, the metal receiving tubes 88, 90 or plated holes can be eliminated if a direct and positive connection is used between the posts of the power connectors and the connector assemblies.

The first connector assembly 12a, the backplane 46, and the power connector 94 are collectively installed in a chassis 102. A power source 104 can be provided with or separate from the chassis 102. The wiring assemblies 62, 64, 66, 68 are all connected to the power source 104. The power source 104 can for example provide 48 VDC electrical power. Connector assemblies 12 of the present disclosure minimize a stand-off height “B” measured from the first planar face 48 to a surface 100 of the farthest standoff terminal lead receivers 74′. This allows other components to be positioned in close proximity to backplane 46 while providing good isolation of the power connections.

According to several aspects, the system 10 for providing electrical power connection across components mounted to a backplane 46 of an electrical chassis includes at least one power terminal 16 having a substantially planar first terminal body portion 18 and a second terminal body portion 22. First and second posts 24a, 24b integrally extend from the second terminal body portion 22. At least one aperture pair 50, 52, 54, 56 is created in the backplane 46 having first and second conductive metal receiving tubes 88, 90. The first and second posts 24a, 24b individually extend into and frictionally engage one of the first or second receiving tubes 88 or 90. At least one wiring assembly 62, 64, 66, 68 has a terminal body 76 connected to the first terminal body portion 18 of the power terminal 16.

According to other aspects, system 10 for providing electrical power connection across components mounted to a backplane 46 of an electrical chassis includes a polymeric material connector body 14. Multiple power terminals 16 each have a substantially planar first terminal body portion 18 and a second terminal body portion 22. Each first terminal body portion 18 is in direct contact with a first or front face 28 of the connector body 14. First and second posts 24a, 24b are integrally connected to the second terminal body portion 22 of each of the power terminals 16 and extend through and beyond the connector body 14. Multiple aperture pairs 50, 52, 54, 56 are created in the backplane 46. Each of the aperture pairs 50, 52, 54, 56 define first and second receiving tubes 88, 90. The first and second posts 24a, 24b of each of the power terminals 16 individually freely extending from the connector body 14 further extend into one of the first or second receiving tubes 88, 90. Multiple wiring assemblies 62, 64, 66, 68 each have a terminal body 76 connected to the first terminal body portion 18 of one of the power terminals 16.

According to further aspects, the connector body 14 is eliminated and the power terminals 16a, 16b, 16c, 16d are attached or mounted directly to the first planar face 48 of the backplane 46. The first and second posts 24a, 24b of the power terminals 16a, 16b, 16c, 16d are extended into the metal receiving tubes 88, 90 which also receive the corresponding posts 96, 98 of the power connector 94. The terminal bodies 76 of the wiring assemblies 62, 64, 66, 68 are then mated to the first terminal body portions 18 of the individual ones of the power terminals 16a, 16b, 16c, 16d.

Referring to FIG. 6, multiple connector assemblies 12 such as connector assemblies 12a, 12b, 12c are fastened to a mounting board 105. Mounting board 105 can then be fastened to backplane 46. This configuration allows pre-assembly of multiple connector assemblies away from the backplane 46.

Referring to FIG. 7, according to further aspects a connector assembly 106 is used in place of connector assembly 12. Connector assembly 106 is modified to replace terminals 16 and body apertures 30 with multiple socket members 108. Each socket member 108 is made of a conductive polymeric or metal material and includes an open portion 110 which is directed toward the planar face 48′ of backplane 46′. Multiple pins 112 of a conductive material are fixed in power connector 94′ and include extending portions 114 that are passed entirely through and extend outwardly of the planar face 48′ of backplane 46′. The extending portions 114 are each frictionally received in one of the open portions 110 of the socket members 108. The connector assembly 106 can therefore be installed by pressing the connector assembly onto the extending portions 114 in an installation direction “C” until the extending portions 114 are received in the socket members 108. When the socket members 108 are made of a non-conductive material, each pin 112 is slidably and frictionally received in a conductive metal tube 116 extending through backplane 46′. The conductive metal tubes 116 can individually be electrically connected to connecting pads shown and described in reference to FIG. 8.

Referring to FIG. 8 and again to FIGS. 4 and 7, according to further aspects, connector assemblies 12, 106 can be individually or entirely omitted and a pin 118 (similar to pins 112) extending through backplane 46′ from power connector 94′ can be contacted using an adjacent connection hole 120 and a connecting pad 122. Power from a power source such as 48 VDC power source 104 can be connected to pin 118 via connecting pad 122 directly and without the use of connector assemblies 12.

Referring to FIG. 9, according to further aspects a power distribution connection system 124 is modified from power distribution connection system 10, therefore only the differences will be further discussed. A backplane 126 includes one or more power connectors 94″ mounted to a rear face 128 of the backplane 126. A reduced area trace region 130 is created on a front face 132 of the backplane 126. Additional traces are provided with a daughter board 134 which is connected to backplane 126 using multiple fasteners 136 such as screws. The fasteners 136 are individually inserted through individual apertures 138 created in daughter board 134 and further extended through backplane 126 to electrically couple daughter board 134 to backplane 126. Power plugs 140 are mounted to daughter board 134 to which power supply wiring (not shown) is routed to provide electrical power to power distribution connection system 124. Power planes (not shown) which are included within the construction layers of daughter board 134 direct power from the power plugs 140 to the individual locations of each individual one of the fasteners 136.

Referring to FIG. 10, each fastener such as exemplary fastener 136′ is inserted through one of the apertures 138′ from a daughter board front face 142 and subsequently received in a backplane aperture 144 created in trace region 130 of the backplane 126. Each backplane aperture 144 is individually positioned in a conductive pad 146 such that contact of the conductive pad by the fastener 136′ provides a conductive path from daughter board 134 to backplane 126. Each conductive pad 146 is connected to a separate trace 148 which provides a conductive path to a connection point for individual pins extending through backplane 126 from power connector 94″. After passing through its backplane aperture 144, each fastener 136 receives a threaded nut 150 on a free end to mechanically couple the daughter board 134 to the backplane 126. Each of the apertures 138 is therefore individually co-axially aligned with one of the backplane apertures 144.

Referring to FIG. 11 and again to FIG. 10, multiple aligned pairs of conductive pads are arranged in the trace region 130 of the backplane 126 each having a backplane aperture. For example a second backplane aperture 152 is created through a second conductive pad 154, both of which are positioned above (as seen by the viewer in FIG. 11) conductive pad 146 within a thickness of the backplane 126. A second trace 156 connected to second conductive pad 154 is electrically isolated from trace 148 and each other trace of trace region 130. Each of the traces such as second trace 156 is conductively connected to a power pin of the power connectors 94″, for example a power pin 158 which extends through backplane 126. Fasteners such as a fastener 160 connect through apertures of backplane 126 to mount power connectors 94″ shown and described in reference to FIG. 12.

Referring to FIG. 12 and again to FIGS. 9-11, multiple conductive pads which are similar to conductive pad 146 are also individually created on the rear face 128 of backplane 126, such as a conductive pad 162, each connectively coupled to one of the conductive pads in the trace region 130 on the front face 132 when each fastener 136 is inserted through one of the backplane apertures 144. A nut 150 applied to each fastener 136 also contacts the conductive pad 162, and positively couples the daughter board 134 to the backplane 126.

Referring to FIG. 13, according to further aspects a power distribution connection system 166 is modified from power distribution connection system 124 therefore the differences will be further discussed. Power distribution system 166 includes a backplane 168 having multiple power connectors 94′″ connected to the backplane 168 using multiple power pins 170 each received in a separately created aperture of the backplane 168. A daughter board 172 is coupled to backplane 168 by multiple eye-of-the-needle pins 174 connected to daughter board 172 and frictionally coupled to backplane 168 within the individual apertures occupied by each of the power pins 170. Each of the eye-of-the-needle pins 174 therefore includes a first pin portion 176 that is frictionally received in the individual aperture occupied by one of the power pins 170.

Referring to FIG. 14 and again to FIGS. 5 and 13, multiple apertures 178 are created in daughter board 172 which are each co-axially aligned with one of multiple apertures 180 created in backplane 168. Each of the apertures 178 and 180 can receive a metal receiving tube similar to metal receiving tube 88 which slidably and frictionally receives one of the eye-of-the-needle pins 174 to connect traces in the daughter board 172 to the power connectors 94′″.

Referring to FIG. 15 and again to FIGS. 13-14, each eye-of-the-needle pin 174 includes the first pin portion 176 and an oppositely directed second pin portion 182. The first and second pin portions 176, 182 are integrally connected to a cross member 184. The first pin portion 176 extends away from a first edge 186 of cross member 184, and the second pin portion extends away from a second edge 188 of cross member 184. The first edge 186 provides a contact line between eye-of-the-needle pin 174 and the backplane 180, and second edge 188 provides a contact line between eye-of-the-needle pin 174 and the daughter board 172. According to several aspects a length “D” of first pin portion 176 is shorter than a length “E” of second pin portion 182 due to a reduced thickness of the backplane 168 which also accommodates the length of the power pins of the power connectors 94″. Eye-of-the-needle pin 174 also provides a first convex curved surface 190 and an oppositely directed second convex curved surface 192 for the first pin portion 176, as well as a cavity 194. Cavity 194 allows the first convex curved surface 190 and the second curved surface 192 to contract toward each other during installation of first pin portion 176. Eye-of-the-needle pin 174 further provides a third convex curved surface 196 and an oppositely directed fourth convex curved surface 198 for the second pin portion 182, as well as a cavity 200, which function similar to the same features of first pin portion 176.

The system of the present disclosure offers several advantages. A plurality of power distribution connectors are located substantially adjacent to each of the module power connectors. Each power distribution connector provides electrical connectivity to an external power source. Power is electrically coupled between each power distribution connector and the adjacent module power connector(s) in such a way as to minimize or eliminate the use of backplane conductive layers. Instead of bussing power to and using a layer of the backplane as done in known systems, power is transferred through the backplane and delivered directly to the front card slots of the chassis without going through any layer of the backplane. According to several aspects, there is a one-to-one correspondence between power distribution connectors and module power connectors; each power distribution connector supplies power directly to its associated module connector without using any backplane layers, therefore backplane material and construction cost savings may be substantial.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A system for providing electrical power connection across components mounted to a backplane of an electrical chassis, comprising:
a backplane having oppositely directed first and second faces and multiple through apertures extending through the backplane;
a power connector mounted to the second face having conductive members aligned with individual ones of the through apertures; and
a component positioned on the first face directly and conductively connected using coupling members extending into individual ones of the apertures to one of the conductive members of the power connector.

2. The system for providing electrical power connection across components mounted to a backplane of an electrical chassis of claim 1, wherein the component comprises at least one power terminal having a substantially planar first terminal body portion and a second terminal body portion, the coupling members defining first and second posts integrally extending from the second terminal body portion into individual ones of the apertures.

3. The system for providing electrical power connection across components mounted to a backplane of an electrical chassis of claim 2, further including at least one wiring assembly having a terminal body directly connected to the first terminal body portion of the power terminal.

4. The system for providing electrical power connection across components mounted to a backplane of an electrical chassis of claim 2, wherein the multiple through apertures further include at least one aperture pair created in the backplane having first and second conductive metal receiving tubes, the first and second posts individually extending into and frictionally engaging one of the first or second receiving tubes.

5. The system for providing electrical power connection across components mounted to a backplane of an electrical chassis of claim 4, further including a polymeric material connector body, the first terminal body portion of the at least one power terminal in contact with a front face of the connector body and the first and second posts extending through the connector body to be received in the first or second receiving tubes.

6. The system for providing electrical power connection across components mounted to a backplane of an electrical chassis of claim 2, wherein the at least one power terminal includes first and second power terminals.

7. The system for providing electrical power connection across components mounted to a backplane of an electrical chassis of claim 6, wherein the connector body includes a raised portion separating the first and second power terminals.

8. The system for providing electrical power connection across components mounted to a backplane of an electrical chassis of claim 2, wherein the connector body includes a planar rear face oppositely facing with respect to a front face, the rear face abutted to the first face of the backplane.

9. The system for providing electrical power connection across components mounted to a backplane of an electrical chassis of claim 2, wherein a first planar face of the backplane contacted by the connector body includes no electrical traces such that electrical connection across the backplane is provided by only the first and second posts to the power connector.

10. The system for providing electrical power connection across components mounted to a backplane of an electrical chassis of claim 4, wherein the power connector posts individually extend into and frictionally engage one of the first or second receiving tubes.

11. The system for providing electrical power connection across components mounted to a backplane of an electrical chassis of claim 4, wherein each of the first and second posts defines an “eye-of-the-needle” geometry having opposed curved surfaces compressed toward each other when the first and second posts are received in the first or second receiving tubes.

12. The system for providing electrical power connection across components mounted to a backplane of an electrical chassis of claim 2, wherein the at least one power terminal includes first and second power terminals, the first power terminal defining a power connection and the second power terminal defining a ground connection.

13. The system for providing electrical power connection across components mounted to a backplane of an electrical chassis of claim 2, wherein the at least one power terminal includes first, second, third and fourth power terminals, the first and second power terminals each defining a power connection and the third and fourth power terminals each defining a ground connection.

14. The system for providing electrical power connection across components mounted to a backplane of an electrical chassis of claim 1, wherein the component includes a daughter board having multiple traces with individual conductive pads, each of the pads coupled to one of the conductive members of the power connector by a fastener extending through both the daughter board and the backplane.

15. The system for providing electrical power connection across components mounted to a backplane of an electrical chassis of claim 1, wherein the component defines a daughter board having multiple traces, each of the traces electrically coupled to one of the conductive members of the power connector by one of multiple pins extending from the daughter board individually received in the apertures of the backplane.

16. A system for providing electrical power connection across components mounted to a backplane of an electrical chassis, comprising:
a backplane having multiple apertures and front and rear faces;
a daughter board facing the front face of the backplane, the daughter board having multiple traces with individual conductive pads;
a power connector connected to the rear face of the backplane having multiple conductive members; and
multiple fasteners each extending through both the daughter board and into the backplane electrically couple each of the conductive pads of the daughter board to one of the conductive members of the power connector.

17. The system for providing electrical power connection across components mounted to a backplane of an electrical chassis of claim 16, wherein each aperture includes a conductive metal receiving tube frictionally receiving one of the fasteners.

18. The system for providing electrical power connection across components mounted to a backplane of an electrical chassis of claim 17, wherein the fasteners each define a conductive metal eye-of-the-needle fastener frictionally engaged in the conductive metal receiving tube.

19. The system for providing electrical power connection across components mounted to a backplane of an electrical chassis of claim 16, further including multiple conductive pads individually created on the rear face of the backplane.

20. The system for providing electrical power connection across components mounted to a backplane of an electrical chassis of claim 19, wherein the fasteners each extend entirely through the backplane.

21. The system for providing electrical power connection across components mounted to a backplane of an electrical chassis of claim 20, further including a threaded nut connected to each of the fasteners, each threaded nut contacting one of the conductive pads individually created on the rear face of the backplane.

22. A system for providing electrical power connection across components mounted to a backplane of an electrical chassis, comprising:
a polymeric material connector body;
multiple power terminals each having a substantially planar first terminal body portion and a second terminal body portion, each first terminal body portion in contact with a first face of the connector body;
first and second posts integrally connected to the second terminal body portion of each of the power terminals and extending through the connector body;
multiple aperture pairs created in a backplane, each of the pairs defining first and second receiving tubes, the first and second posts of each of the power terminals individually freely extending from the connector body further extending into one of the first or second receiving tubes; and
multiple wiring assemblies each having a terminal body connected to the first terminal body portion of one of the power terminals.

23. The system for providing electrical power connection across components mounted to a backplane of an electrical chassis of claim 22, further including a power connector mounted to a second planar face of the backplane oppositely directed with respect to the first planar face, the power connector having third and fourth posts each extending into one of the first or second receiving tubes.

24. The system for providing electrical power connection across components mounted to a backplane of an electrical chassis of claim 23, wherein a first planar face of the backplane contacted by the connector body includes no electrical traces such that electrical connection across the backplane is provided by only individual ones of the first and second posts connected to individual ones of the posts of the power connector mounted to a second planar face of the backplane.

25. The system for providing electrical power connection across components mounted to a backplane of an electrical chassis of claim 23, wherein the first and second receiving tubes individually include one of a first or second conductive metal receiving tube.

26. The system for providing electrical power connection across components mounted to a backplane of an electrical chassis of claim 25, wherein each of the first and second posts defines an “eye-of-the-needle” geometry having opposed curved surfaces compressed toward each other when the first and second posts are received in the first or second receiving tube.
